(19) United States
(12) Patent Application Publication
(10) Pub. No.: US 2015/0180258 A1
(43) Pub. Date: Jun. 25, 2015

(54) BATTERY TYPE DETERMINATION DEVICE AND BATTERY-DRIVEN ELECTRONIC DEVICE INCLUDING THE SAME

(71) Applicant: OPTEX CO., LTD., Shiga (JP)

(72) Inventors: Takao UJIKE, Otsu-shi (JP); Shinya NISHIMURA, Otsu-shi (JP); Hiroshi MAKINO, Otsu-shi (JP); Chihiro MORITA, Otsu-shi (JP)

(73) Assignee: OPTEX CO., LTD., Shiga (JP)

(21) Appl. No.: 14/577,563

(22) Filed: Dec. 19, 2014

(30) Foreign Application Priority Data
Dec. 20, 2013 (JP) 2013-263290

(51) Int. Cl. H02J 7/00; G01R 31/36

(52) U.S. Cl. CPC H02J 7/0063; G01R 31/3665; H02J 2007/0098; H02J 2007/0067

(57) ABSTRACT

Provided are a battery type determination device with a simple configuration capable of easily and reliably determining the types of a plurality of batteries irrespective of shapes and characteristics of the batteries, and a battery-driven electronic device that includes the battery type determination device and allows usage of plural types of batteries. The battery type determination device is used in a battery-driven electronic device operable with plural types of batteries having different shapes and characteristics, and includes a determination signal generator for generating a determination signal that is allocated for each of the plural types of batteries without depending on shapes and characteristics of the batteries and is formed by combination of binary signals prescribed for each type of battery; and a determination controller for determining the type of each battery based on the generated determination signal.

### CROSS REFERENCE TO THE RELATED APPLICATION

This application is based on and claims Convention priority to Japanese patent application No. 2013-263290, filed Dec. 20, 2013, the entire disclosure of which is herein incorporated by reference as a part of this application.

### BACKGROUND OF THE INVENTION

1. Field of the Invention

The present invention relates to a battery type determination device for determining plural types of batteries having different shapes and characteristics, and a battery-driven electronic device including the battery type determination device.

2. Description of Related Art

Conventionally, there is known an electronic device such as a security sensor which detects an intruder, using a detection beam or ray for object detection such as an infrared ray (IR). The security sensor has a detection unit composed of, for example, a beam projector which emits a detection beam and a beam receiver which is placed opposite to the beam projector and which receives the detection beam and outputs a detection signal. The security sensor detects an intruder based on change in the amount of the received beam (detection signal level), which change is caused when the intruder intercepts the detection beam.

In recent years, for the purpose of reduction in power consumption, reduction in time and effort for wiring work, or the like, an increased number of security sensors have been designed to be driven by batteries provided therein, and various types of batteries such as manganese dioxide lithium battery (CR) and thionyl chloride lithium battery (ER) have been used. In such a case, for the batteries, it is necessary to perform control for detecting voltage reduction due to battery level or capacity reduction, control according to the characteristic of each battery, and the like. However, since the control content differs depending on the type of each battery, it is firstly necessary to determine the type of the battery.

As an example of the above, a technology of determining the type of a battery from a result of comparison between the battery voltage in a full-charge state and a predetermined threshold value is known by, for example, JP Laid-open Patent Publication No. H07-260906. In addition, a technology of determining the type and the characteristic of a battery from an internal resistance of the battery is known by, for example, JP Laid-open Patent Publication No. 2000-261975, and a technology of specifying the type of a battery based on the shape of the battery is also known.

However, in such a conventional case of determining the type of a battery from a voltage or an internal resistance of the battery, a circuit for determining the type of a battery is complicated, and also, power of the battery is consumed in the determination, thus contradicting the purpose of prolonging a battery life. In addition, in the case of determining the type of a battery based on the shape of the battery, if plural types of batteries are used, it is necessary to prepare a plurality of determination units having structures adapted to the respective shapes of batteries, thus increasing time and effort.

Meanwhile, in an electronic device such as a security sensor, in the case where plural types of batteries having different battery capacities and characteristics are mounted therein, a threshold value for detecting voltage reduction differs depending on each type, and in addition, it may be necessary to perform specific control such as a discharge operation for a lithium battery (ER). However, these have not been sufficiently addressed. Further, if the ambient temperature changes, battery voltage also changes. Therefore, it is necessary to correct the voltage in order to compensate the voltage reduction in accordance with the above change.

On the other hand, in the case of battery-driven security sensor, a battery cannot be replaced for a long time in some installation places. In such a case, a battery with high cost but a long life is selected. In the case where battery replacement is easy, for example, a battery with a short life but low cost is selected. Thus, there is a demand for ensuring freedom to select batteries having characteristics to suit the usage purpose. However, in some security sensors, due to control therefore, the types of batteries that can be used are limited.

### SUMMARY OF THE INVENTION

An object of the present invention is to solve the above mentioned problems and to provide a battery type determination device with a simple configuration capable of easily and reliably determining the types of a plurality of batteries irrespective of the shapes and the characteristics of the batteries, and a battery-driven electronic device that includes the battery type determination device and that allows usage of plural types of batteries.

In order to attain the above object, a battery type determination device according to one aspect of the present invention, which is used in a battery-driven electronic device operable with plural types of batteries having different shapes and characteristics, includes: a determination signal generator for generating a determination signal allocated for each of the plural types of batteries without depending on the shapes and the characteristics of the batteries, the determination signal being formed by combination of binary signals predetermined for each type of battery; and a determination controller for determining the type of each battery based on the generated determination signal. Here, the term “characteristic” refers to a characteristic relevant to battery performance, such as battery voltage in a full-charge state or a discharge characteristic. The term “types of battery” refers to kinds of batteries in which materials of positive electrode, negative electrode, separator, or electrolyte are different from each other.

According to the above configuration, since, for each of a plurality of batteries, a determination signal formed by combination of binary signals predetermined without depending on the shapes and the characteristics of the batteries is generated, it is possible to determine the types of batteries irrespective of the shapes and the characteristics of the batteries. In addition, even if the types of batteries are increased, it is possible to easily adapt thereto merely by increasing the number of binary signals to be combined or the bit number of binary signals. Thus, the types of a plurality of batteries can be easily and reliably determined.

In the present invention, the determination controller may specify the type of each battery, based on an input signal from a plurality of accommodation bodies for respectively accommodating the plural types of batteries. In this case, the types of a plurality of batteries can be further easily determined.

The determination signal generator may have a plurality of signal lines for determination, which lines are connected to each of the plural types of batteries, and the determination controller may specify the type of each battery, based on presence or absence of an input signal from each of the signal line for determination. In this case, the types of a plurality of batteries can be further easily determined.

A battery-driven electronic device according to another aspect of the present invention includes the battery type determination device and a specific controller for performing specific control for each battery so as to suppress voltage reduction of the battery, in accordance with the type of the battery. Therefore, it is possible to easily determine the types of a plurality of batteries and to adapt to the characteristic of each battery, thus allowing usage of plural types of batteries.

Preferably, a threshold value corrector is further provided for correcting a threshold value for determining voltage reduction of each battery, in accordance with the type of the battery and an ambient temperature. Therefore, it is possible to easily determine the types of a plurality of batteries and to adapt to the characteristic of each battery, thus allowing usage of plural types of batteries.

Preferably, the battery-driven electronic device is a battery-driven security sensor. Therefore, it is possible to select and use an optimum type of battery in accordance with an installation place. Preferably, power sources in a plurality of systems are provided, and an operation state of the power source in each system is determined based on a determination signal allocated for each kind of battery of the power source in each system. Therefore, it is possible to easily determine whether or not the power source in each system is normally operated.

Any combination of at least two constructions, disclosed in the appended claims and/or the specification and/or the accompanying drawings should be construed as included within the scope of the present invention. In particular, any combination of two or more of the appended claims should be equally construed as included within the scope of the present invention.

### BRIEF DESCRIPTION OF THE DRAWINGS

In any event, the present invention will become more clearly understood from the following description of preferred embodiments thereof, when taken in conjunction with the accompanying drawings. However, the embodiments and the drawings are given only for the purpose of illustration and explanation, and are not to be taken as limiting the scope of the present invention in any way whatsoever, which scope is to be determined by the appended claims. In the accompanying drawings, like reference numerals are used to denote like parts throughout the several views, and:

FIG. 1 is a side view showing a battery-driven security sensor according to a first embodiment of the present invention;

FIG. 2 is an exploded perspective view showing the security sensor in FIG. 1;

FIG. 3 is a block diagram showing a battery type determination device according to the first embodiment of the present invention;

FIG. 4 is a block diagram showing the entire security sensor in FIG. 1;

FIG. 5 is a block diagram showing a battery type determination device according to a second embodiment; and

FIG. 6 is a block diagram showing a battery type determination device according to an alternative embodiment.

### DESCRIPTION OF EMBODIMENTS

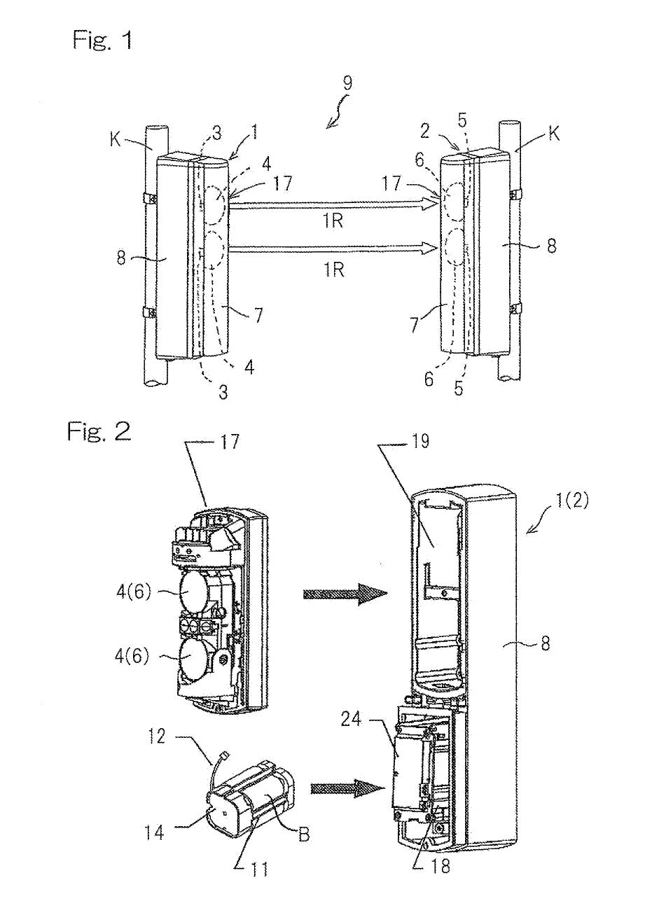

Hereinafter, embodiments of the present invention will be described with reference to the drawings. FIG. 1 is a perspective view showing a battery-driven security sensor 9 according to a first embodiment of the present invention. FIG. 2 is an exploded perspective view showing the security sensor in FIG. 1. As shown in FIG. 1, the security sensor 9 is, for example, an AIR-type (active infrared ray type) security sensor having a beam projector 1 and a beam receiver 2 which is placed opposite to the beam projector 1 and which has two elements receiving detection beams or rays such as two infrared rays IR emitted from the beam projector 1. The beam projector 1 and the beam receiver 2 are each mounted on a mounting portion K on, such as, a pole or a wall.

When an infrared ray IR from the beam projector 1 is intercepted by an object, the security sensor 9 detects the object based on change in the signal level of a detection signal (the amount of the infrared ray) received by the opposite beam receiver 2, and outputs an alarm signal.

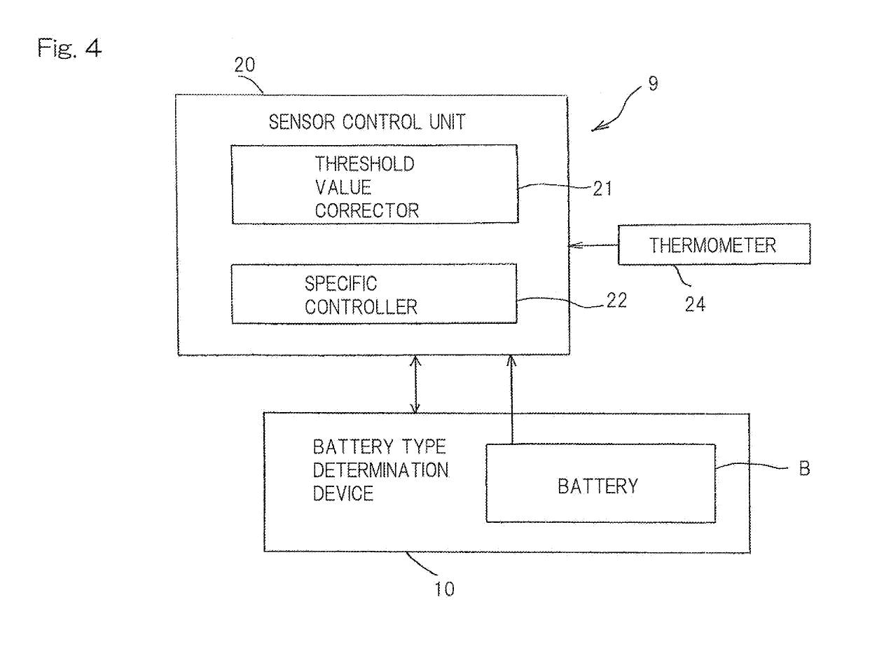

The beam projector 1 and the beam receiver 2 each have a sensor cover 7 and a casing 8. For example, a pair of upper and lower beam emitting elements 3 and a pair of upper and lower beam projecting lenses 4 of the beam projector 1 and a pair of upper and lower beam receiving elements 5 and a pair of upper and lower beam receiver lenses 6 of the beam receiver 2 form sensor units 17 as shown in FIG. 2, which are held at upper portions in the respective casings 8. Sensor control units 20 (FIG. 4) for respectively controlling the beam projector 1 and the beam receiver 2, batteries B which are driving power sources, and the like are held at lower portions in the casings 8. Battery boxes 11 which are a plurality of accommodation bodies corresponding to plural types of batteries for respectively accommodating the batteries are accommodated in a battery box accommodation portion 18. In the case of wirelessly transmitting an alarm signal, a wireless transmitter is accommodated in a wireless transmitter accommodation portion 19 provided at an upper portion in the casing 8.

In the case where the battery boxes 11 are not provided, the battery B is mounted on an electrode board 24 provided in the casing 8. In addition, in the case where the casing 8 has a back box portion (not shown), the battery box accommodation portion 18 and the wireless transmitter accommodation portion 19 may be disposed in the back box portion.

As the battery B to be accommodated in the battery box 11 in FIG. 2, for example, a thionyl chloride lithium battery (a first battery ER) with a voltage of 3.6V and a cylindrical manganese dioxide lithium battery (a second battery CR) with a voltage of 3V are used. The first battery ER, although its cost is high, has a long battery life, and it is necessary to periodically discharge in order to break a chloride lithium coating. The second battery CR has a short life but its cost is low. In the battery-driven security sensor 9, a battery type can be selected according to the purpose of usage. For example, the first battery ER is selected for an installation place where battery replacement cannot be performed for a long time, and the second battery CR is used for an installation place where battery replacement can be easily performed. Although there is a voltage difference between both batteries to be used, supply voltage to the security sensor 9 is adjusted by a power supply circuit (not shown).

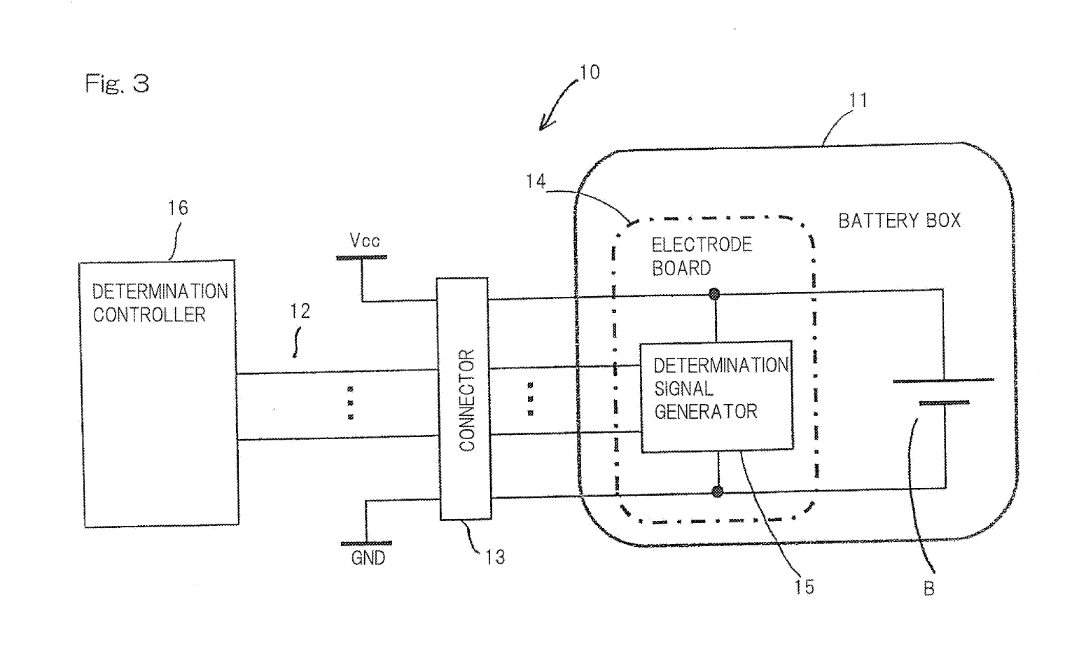

FIG. 3 is a block diagram showing a battery type determination device 10 according to the first embodiment of the present invention. The battery type determination device 10 has the electrode board 14 in the battery box 11 which accommodates the battery, instead of an aforementioned electrode board 24, which the electrode board 14 is similar with the electrode board 24, and a determination signal generator 15 is mounted on the electrode board 14. In addition, a determination controller 16 is provided which determines the type of the battery B based on a determination signal generated by the determination signal generator 15. Between the determination signal generator 15 and the determination controller 16, a plurality of signal lines (harness) 12 for determination are connected via a connector 13.

The determination signal generator 15 generates and outputs determination signals that are allocated for plural types of batteries without depending on the shapes and the characteristics of the batteries, i.e., irrespective of the shapes and the characteristics of the batteries, which determination signals are more specifically formed by combination of binary signals predetermined for each battery type. Based on these determination signals from the plurality of battery boxes 11 for respectively accommodating plural types of batteries B, the determination controller 16 specifies the type of each batter B. The battery boxes 11 are dedicated to the respective types of batteries and accommodate the respective batteries. The input signals from the battery boxes 11, i.e., the determination signal generator 15, are signals from signal lines that are connected to the battery boxes 11 and provided separately from an electric wiring connected to a positive electrode and a negative electrode of each battery B.

The determination signal generator 15 has a configuration in which, for example, a pull-up resistor and a pull-down resistor are provided between a Vcc power supply (5V) and a ground (0V), and the signal lines 12 are connected to the pull-up resistor and the pull-down resistor. In this case, a determination signal is generated based on presence or absence of a pull-up resistor or a pull-down resistor on a specific signal line 12 for determination. That is, if a pull-up resistor is provided on a specific signal line 12 for determination, 5V (H of a binary signal indicating the High) is outputted, and if a pull-down resistor is provided on a specific signal line 12 for determination, 0V (L of a binary signal indicating the Low) is outputted.

If the types of batteries B are increased, by increasing the number of signal lines 12 for determination, a determination signal with an increased bit number of binary signals, e.g., in the case of 3 bits, a combination of HLL binary signal, is obtained. Thus, even if the types of batteries are increased, it is possible to easily adapt to the plural types of batteries merely by increasing the bit number of binary signals.

The determination signal generator 15 generates a binary signal with a pull-up circuit and/or a pull-down circuit, but alternatively, the determination signal generator 15 may generate a binary signal from a logic IC.

The determination signal generator 15 in the battery box 11 and the determination controller 16 are connected by the signal lines (harnesses) 12 for determination via the connector 13, but the electrode board 14 in the battery box 11 and the determination controller 16 may be directly connected.

As shown in FIG. 4, the battery-driven security sensor (electronic device) 9 has a sensor control unit 20, besides the above battery type determination device 10. The sensor control unit 20 includes a threshold value corrector 21 which corrects a threshold value for determining voltage reduction in accordance with the type of each battery B and the ambient temperature, and a specific controller 22 which performs specific control for each battery B so as to suppress battery voltage reduction in accordance with the type of each battery B. The ambient temperature is inputted from a thermometer 24. In this example, both of the threshold value corrector 21 and the specific controller 22 are provided, but only one of them may be provided.

Generally, the battery-driven security sensor 9 regularly monitors reduction in a battery level or capacity by comparison between voltage of each battery B and the threshold value, and the battery level voltage varies to increase or decrease depending on the battery type or change in the ambient temperature. Therefore, for example, if the temperature increases, the voltage increases, and therefore the threshold value needs to be increased. Accordingly, the threshold value corrector 21 corrects the threshold value to increase or decrease it for determining battery voltage reduction, in accordance with the type of each battery and the ambient temperature.

The correction of the threshold value is performed by, for example, changing reference voltage inputted into a comparator (not shown) that compares voltage of each battery B. Alternatively, voltage of each battery B is constantly monitored through sampling by an A/D converter (not shown), and the correction is performed in accordance with change in the voltage.

In the case of, for example, the first battery ER, the specific controller 22 needs to periodically perform discharge in order to break a chloride lithium coating. At this time, if the battery life is close to the end, the voltage reduces immediately by the discharge and the first battery ER becomes unable to be used. Therefore, in order to prevent this, control of stopping the discharge is performed by the specific controller 22. In addition, in the case of, for example, the second battery CR, when reduction in the remaining capacity or level of the voltage is detected, control of reducing consumption current in the circuits of the beam projector 1 and the beam receiver 2 is performed by the specific controller 22. That is, in the beam projector 1, for example, beam emission pulse current for emitting an infrared ray IR is limited or a beam emission pulse width is narrowed, whereby beam emission power is reduced. In the beam receiver 2, control is performed such that, for example, an automatic gain adjustment function is limited or stopped whereby operation current in the circuit is reduced, or a sampling period for a beam reception signal is elongated whereby operation time of a microcomputer in the sensor control unit 20 is shortened.

Thus, the battery-driven security sensor 9 can easily determine the types of batteries by the battery type determination device 10 and can adapt to the characteristic of each battery, thereby allowing usage of plural types of batteries.

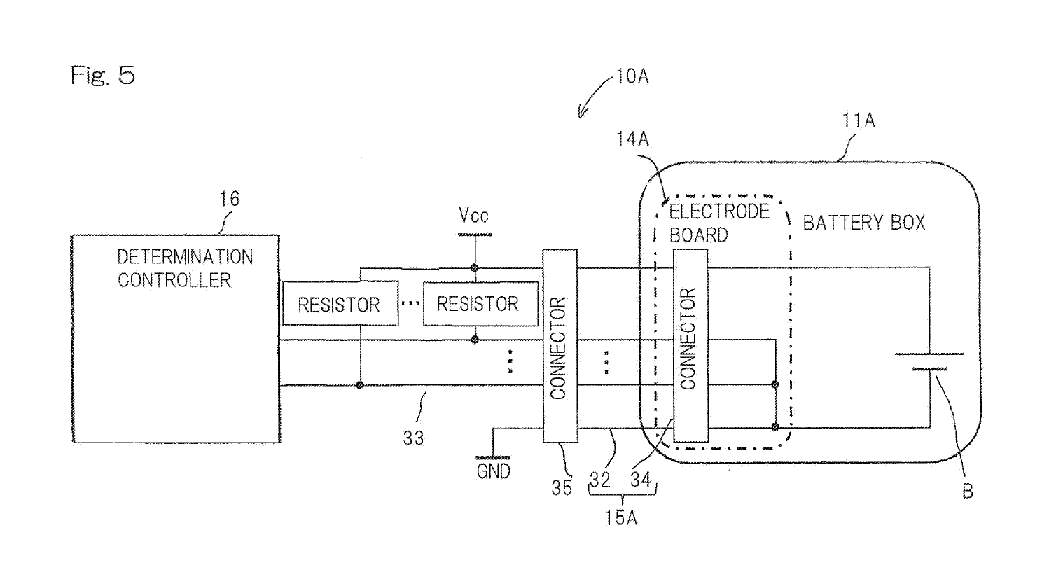

FIG. 5 is a block diagram showing a battery type determination device 10A according to a second embodiment of the present invention. Unlike the first embodiment, a determination signal generator 15A has, for each of plural types of batteries B, a plurality of signal lines (harnesses) 32 for determination which are connected to the positive electrode +and/or the negative electrode—of the battery B, and outputs a determination signal for specifying each battery B based on presence or absence of each input signal from these signal lines 32 for determination. A Vcc power supply is connected to signal lines 33 for determination via resistors, and is connected to the signal lines 32 for determination via a connector 35. A connector 34 in an electrode board 14A and the signal lines 32 for determination form the determination signal generator 15A. The provision of the connector 34 can omit the determination signal generator 15 in FIG. 3. The other configuration is the same as in the first embodiment.

In FIG. 5, the determination signal generator 15A is configured such that, for example, for the second battery CR, two signal lines 32 for determination are connected to the earth (GND), and a determination signal with, for example, LL binary signals is outputted based on input signals from the two signal lines 32 for determination. On the other hand, for the first battery ER, although not shown, one of two signal lines 32 for determination is connected to the earth (GND) and the other one is not connected to the earth (GND), that is, connected to the Vcc power supply or opened, and a determination signal with, for example, LH binary signals is outputted based on input signals from the two signal lines 32 for determination.

Thus, in the present invention, since, for each of a plurality of batteries, a determination signal formed by combination of binary signals predetermined without depending on the shape and the characteristic of each battery is generated, it is possible to determine the types of batteries irrespective of the shapes and the characteristics of the batteries. In addition, even if the types of batteries are increased, it is possible to easily adapt thereto merely by increasing the number of binary signals to be combined. Thus, the types of a plurality of batteries can be easily and reliably determined.

In the above embodiments, as a battery-driven electronic device, a battery-driven security sensor of AIR type is employed. Without limitation to this, the above configurations may be applied to a security sensor of PIR type, or may be applied to another battery-driven electronic device such as an object detection device or the like. In addition, although an infrared ray is used as a detection beam, without limitation to this, a visible ray, a microwave, a laser, or the like may be used.

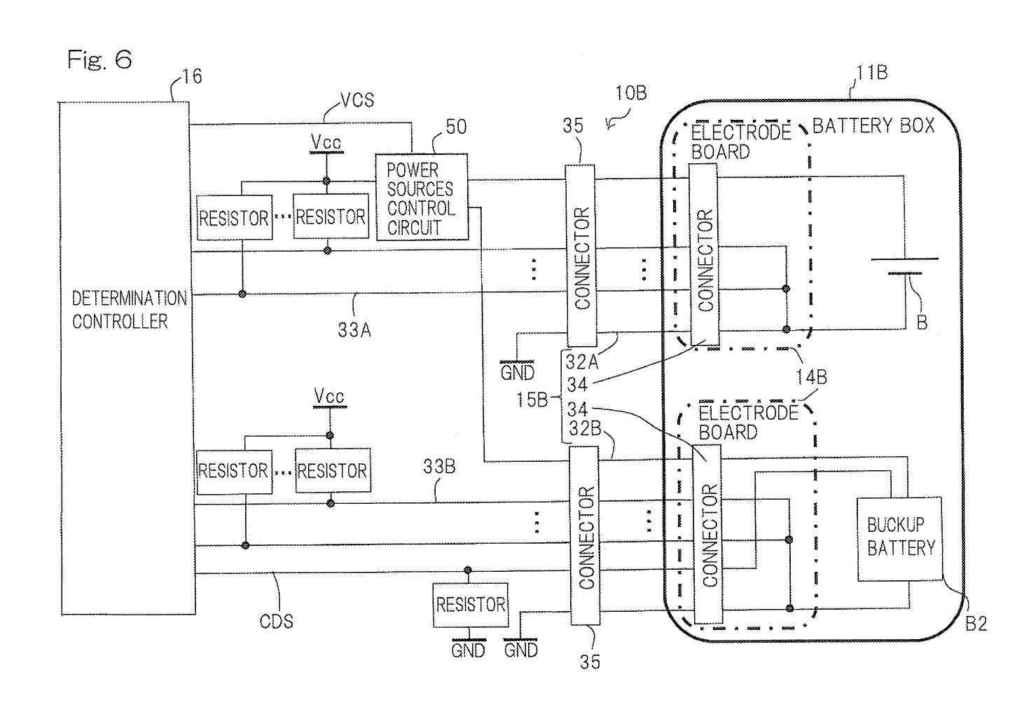

In the above embodiments, a battery-driven electronic device that is operable with plural types of batteries is used. However, the above configurations may be applied to an electronic device that has a plurality of systems, e.g., two systems of power sources, including a backup battery or the like, and that can determine an operation state of the power source in each system based on a determination signal allocated for a battery of the power source in the system. FIG. 6 is a block diagram showing a battery type determination device according to this alternative embodiment. The signal lines 32A and 33A connected thereto are dedicated to the battery B. The signal lines 32B and 33B connected thereto are dedicated to the backup battery B2. In this case, it is possible to easily determine whether or not each power source in the example two systems is normally operated, based on whether or not a determination signal allocated for each power source is generated. In addition, whether or not the backup battery B2 is connected is determined by the determination controller 16 depending on whether or not a connection determination signal line CDS is connected. In the embodiment in FIG. 6 connection of the backup battery B2 is determined by detection of the high signal from the connection determination signal line CDS. Also, selective use of the battery B or the backup battery B2 is conducted by switching function in a power sources control circuit 50 depending on a power sources control signal line VCS from the determination controller 16. The output lines from a plurality of the battery B are connected together in parallel, via a diode respectively.

Although the present invention has been fully described in connection with the preferred embodiments thereof with reference to the accompanying drawings which are used only for the purpose of illustration, those skilled in the art will readily conceive numerous changes and modifications within the framework of obviousness upon the reading of the specification herein presented of the present invention. Accordingly, such changes and modifications are, unless they depart from the scope of the present invention as delivered from the claims annexed hereto, to be construed as included therein.

### REFERENCE NUMERALS

9 . . . battery-driven security sensor
10 . . . battery type determination device
11 . . . accommodation body (battery box)
14, 24 . . . electrode board
15 . . . determination signal generator
16 . . . determination controller
20 . . . sensor control unit
21 . . . threshold value corrector
22 . . . specific controller
B . . . battery

What is claimed is:

1. A battery type determination device used in a battery-driven electronic device operable with plural types of batteries having different shapes and characteristics, the battery type determination device comprising:
a determination signal generator configured to generate a determination signal allocated for each of the plural types of batteries without depending on the shapes and the characteristics of the batteries, the determination signal being formed by combination of binary signals predetermined for each type of battery; and
a determination controller configured to determine the type of each battery based on the generated determination signal.

2. The battery type determination device as claimed in claim 1, wherein the determination controller specifies the type of each battery, based on an input signal from a plurality of accommodation bodies for respectively accommodating the plural types of batteries.

3. The battery type determination device as claimed in claim 1, wherein the determination signal generator has a plurality of signal lines for determination, which lines are connected to each of the plural types of batteries, and the determination controller specifies the type of each battery, based on presence or absence of an input signal from each of the signal line for determination.

4. A battery-driven electronic device comprising:
the battery type determination device as claimed in claim 1; and
a specific controller configured to perform specific control for each battery so as to suppress voltage reduction of the battery, in accordance with the type of the battery.

5. A battery-driven electronic device comprising:
the battery type determination device as claimed in claim 1; and
a threshold value corrector configured to correct a threshold value for determining voltage reduction of each battery, in accordance with the type of the battery and an ambient temperature.

6. The battery-driven electronic device as claimed in claim 4, further comprising a threshold value corrector configured to correct a threshold value for determining voltage reduction of each battery, in accordance with the type of the battery and an ambient temperature.

7. The battery-driven electronic device as claimed in claim 4, wherein the battery-driven electronic device is a battery-driven security sensor.

8. The battery-driven electronic device as claimed in claim 4, wherein power sources in a plurality of systems are provided, and an operation state of the power source in each system is determined based on a determination signal allocated for each kind of battery of the power source in each system.
